(19) United States
(12) Patent Application Publication
(10) Pub. No.: US 2011/0108087 A1
(43) Pub. Date: May 12, 2011

(54) Photovoltaic Modules with Integrated Devices

(75) Inventors: Steven Croft, Menlo Park, CA (US); Randy Dorn, Santa Clara, CA (US); Ilan Gur, San Francisco, CA (US); Bruce Hachtmann, San Martin, CA (US); Dennis Hollars, San Jose, CA (US); Shefali Jaiswal, Dublin, CA (US); Puthur Paulson, Cupertino, CA (US); David Pearce, Saratoga, CA (US); Kannan Ramanathan, San Jose, CA (US); William Sanders, Mountain View, CA (US); Ben Tarbell, Palo Alto, CA (US)

(73) Assignee: MiaSole, Santa Clara, CA (US)

(21) Appl. No.: 13/006,943

(22) Filed: Jan. 14, 2011

Related U.S. Application Data
(63) Continuation of application No. 11/777,391, filed on Jul. 13, 2007.

(51) Int. Cl. H01L 31/042

(52) U.S. Cl. 136/244

(57) ABSTRACT

One photovoltaic module includes a plurality of photovoltaic cells and at least one device selected from a sensor, a data storage device and an indicator. Another photovoltaic module includes a plurality of photovoltaic cells and a flexible circuit configured to act as an antenna for electromagnetic radiation. Methods of using such photovoltaic modules are also disclosed.

### FIELD

The present invention relates generally to photovoltaic devices and methods of using the photovoltaic devices and more particularly to photovoltaic devices with integrated devices and methods of their using.

### BACKGROUND

Many commercial photovoltaic (“PV”) modules are solely passive devices configured with a fixed arrangement of cells, interconnections and output characteristics. Cell to cell interconnections in such devices are made using a tab and string method by soldering copper strips between adjacent cells. Furthermore, many commercial photovoltaic modules are plagued with limitations relating to their manufacture, installation and operation. Such limitations include complexity of forming cell to cell interconnection and configuring multiple customized products, performance degradation from shading, hotspots, and low light, and complexity of installing modules in a variety of locations, each with its own characteristic constraints.

### SUMMARY

According to one embodiment, a photovoltaic module comprises a plurality of photovoltaic cells and at least one device integrated into the module. The device is selected from a sensor configured to detect a change in one or more parameters affecting at least one of the plurality of photovoltaic cells, a data storage device configured to record at least one parameter of at least one of the plurality of photovoltaic cells and an indicator configured to display a status of at least one of the plurality of photovoltaic cells.

According to another embodiment, a photovoltaic module comprises a plurality of photovoltaic cells and a flexible circuit that is integrated in the module and is configured as an antenna for receiving and/or transmitting an electromagnetic radiation signal.

Yet another embodiment is a method of using a photovoltaic module that comprises a plurality of photovoltaic cells. The method comprises monitoring at least one parameter for a change with a sensor integrated in the photovoltaic module and modifying a performance of the photovoltaic module in response to a detected change in the parameter.

### BRIEF DESCRIPTION OF THE DRAWINGS

FIG. 1 schematically illustrates a photovoltaic module that includes two photovoltaic cells and a flexible collector-connector.

FIGS. 2A and 2B schematically illustrate a photovoltaic module that includes two photovoltaic cells and a flexible collector-connector.

FIG. 3 schematically illustrates a photovoltaic module that includes a plurality of photovoltaic cells.

FIG. 4 is a photograph of a flexible Cu(In,Ga)Se₂ (CIGS) cell formed on flexible stainless steel substrate.

FIG. 5 is a photograph illustrating a flexible nature of CIGS cell formed on flexible stainless steel substrate.

FIG. 6 schematically illustrates a photovoltaic module with a smart AC disconnect.

### DETAILED DESCRIPTION OF THE PREFERRED EMBODIMENTS

Unless otherwise specified “a” or “an” means one or more.

An active photovoltaic module contains at least one of sensor, logic, data storage and/or data transmission devices integrated with the module or connected to the module. Such a module can have a wider range of functions, higher efficiency and a greater ease of manufacturing, installation and/or operation compared to existing photovoltaic modules. The term “integrated” as applied to a device means that the device is physically located in the module.

According to one embodiment, a photovoltaic module includes a plurality of photovoltaic cells and at least one additional device selected from a sensor, a data storage device and a status indicator. Preferably, the additional device is integrated in the module.

According to another embodiment, a photovoltaic device comprises a plurality of photovoltaic cells and a flexible circuit configured as an antenna for receiving and/or transmitting an electromagnetic radiation signal. The flexible circuit is used for connecting the photovoltaic cells and, thus, is integrated in the module.

### Photovoltaic Cells

Preferably, but not necessarily, additional devices, such as a sensor, a data storage device, a status indicator or an antenna are integrated or electrically connected to a flexible photovoltaic module described in U.S. patent application Ser. No. 11/451,616, filed on Jun. 13, 2006, incorporated herein by reference in its entirety. This photovoltaic module includes at least two photovoltaic cells and a collector-connector. As used herein, the term “module” includes an assembly of at least two, and preferably three or more electrically interconnected photovoltaic cells, which may also be referred to as “solar cells”. The “collector-connector” is a device that acts as both a current collector to collect current from at least one photovoltaic cell of the module, and as an interconnect, which electrically interconnects the at least one photovoltaic cell with at least one other photovoltaic cell of the module. In general, the collector-connector takes the current collected from each cell of the module and combines it to provide a useful current and voltage at the output connectors of the module.

This collector-connector (which can also be referred to as a flexible circuit or “decal”) preferably comprises an electrically insulating carrier and at least one electrical conductor which electrically connects one photovoltaic cell to at least one other photovoltaic cell of the module.

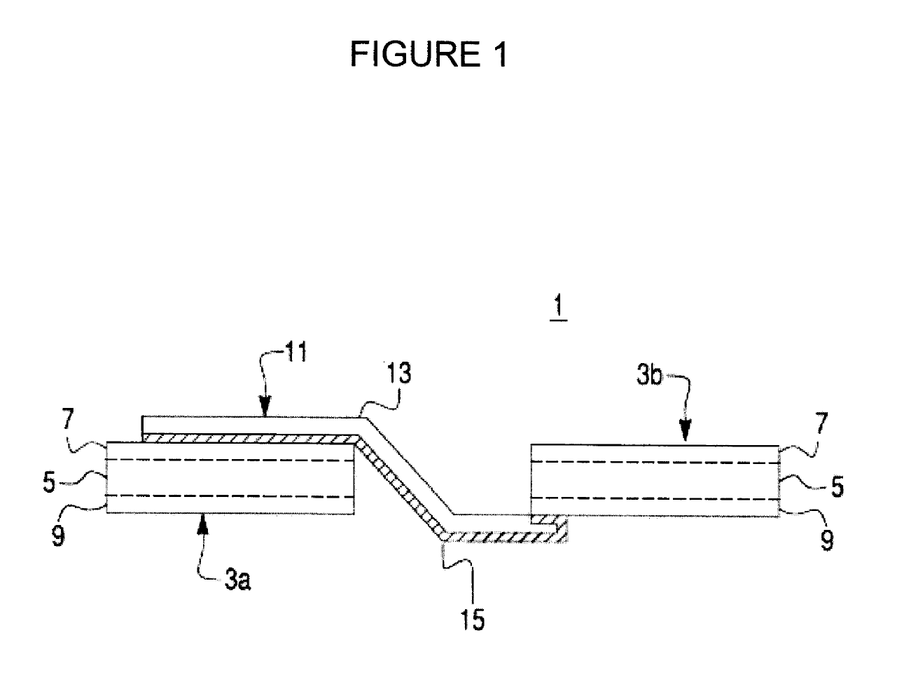

FIG. 1 schematically illustrates a photovoltaic module 1. The module 1 includes first and second photovoltaic cells 3a and 3b. It should be understood that the module 1 may contain three or more cells, such as 3-10,000 cells for example. Preferably, the first 3a and the second 3b photovoltaic cells are plate shaped cells which are located adjacent to each other, as shown schematically in FIG. 1. The cells may have a square, rectangular (including ribbon shape), hexagonal or other polygonal, circular, oval or irregular shape when viewed from the top.

Each cell 3a, 3b includes a photovoltaic material 5, such as a semiconductor material. For example, the photovoltaic semiconductor material may comprise a p-n or p-i-n junction in a Group IV semiconductor material, such as amorphous or crystalline silicon, a Group II-VI semiconductor material, such as CdTe or CdS, a Group I-III-VI semiconductor material, such as CuInSe₂ (CIS) or Cu(In,Ga)Se₂ (CIGS), and/or a Group III-V semiconductor material, such as GaAs or InGaP. The p-n junctions may comprise heterojunctions of different materials, such as CIGS/CdS heterojunction, for example. Each cell 3a, 3b also contains front and back side electrodes 7, 9. These electrodes 7, 9 can be designated as first and second polarity electrodes since electrodes have an opposite polarity. For example, the front side electrode 7 may be electrically connected to an n-side of a p-n junction and the back side electrode may be electrically connected to a p-side of a p-n junction. The electrode 7 on the front surface of the cells may be an optically transparent front side electrode which is adapted to face the Sun, and may comprise a transparent conductive material such as indium tin oxide or aluminum doped zinc oxide. The electrode 9 on the back surface of the cells may be a back side electrode which is adapted to face away from the Sun, and may comprise one or more conductive materials such as copper, molybdenum, aluminum, stainless steel and/or alloys thereof. This electrode 9 may also comprise the substrate upon which the photovoltaic material 5 and the front electrode 7 are deposited during fabrication of the cells.

The module 1 also contains the collector-connector 11, which comprises an electrically insulating carrier 13 and at least one electrical conductor 15. The collector-connector 11 electrically contacts the first polarity electrode 7 of the first photovoltaic cell 3a in such a way as to collect current from the first photovoltaic cell. For example, the electrical conductor 15 electrically contacts a major portion of a surface of the first polarity electrode 7 of the first photovoltaic cell 3a to collect current from cell 3a. The conductor 15 portion of the collector-connector 11 also electrically contacts the second polarity electrode 9 of the second photovoltaic cell 3b to electrically connect the first polarity electrode 7 of the first photovoltaic cell 3a to the second polarity electrode 9 of the second photovoltaic cell 3b.

Preferably, the carrier 13 comprises a flexible, electrically insulating polymer film having a sheet or ribbon shape, supporting at least one electrical conductor 15. Examples of suitable polymer materials include thermal polymer olefin (TPO). TPO includes any olefins which have thermoplastic properties, such as polyethylene, polypropylene, polybutylene, etc. Other polymer materials which are not significantly degraded by sunlight, such as EVA, other non-olefin thermoplastic polymers, such as fluoropolymers, acrylics or silicones, as well as multilayer laminates and co-extrusions, such as PET/EVA laminates or co-extrusions, may also be used. The insulating carrier 13 may also comprise any other electrically insulating material, such as glass or ceramic materials. The carrier 13 may be a sheet or ribbon which is unrolled from a roll or spool and which is used to support conductor(s) 15 which interconnect three or more cells 3 in a module 1. The carrier 13 may also have other suitable shapes besides sheet or ribbon shape.

The conductor 15 may comprise any electrically conductive trace or wire. Preferably, the conductor 15 is applied to an insulating carrier 13 which acts as a substrate during deposition of the conductor. The collector-connector 11 is then applied in contact with the cells 3 such that the conductor 15 contacts one or more electrodes 7, 9 of the cells 3. For example, the conductor 15 may comprise a trace, such as silver paste, for example a polymer-silver powder mixture paste, which is spread, such as screen printed, onto the carrier 13 to form a plurality of conductive traces on the carrier 13. The conductor 15 may also comprise a multilayer trace. For example, the multilayer trace may comprise a seed layer and a plated layer. The seed layer may comprise any conductive material, such as a silver filled ink or a carbon filled ink which is printed on the carrier 13 in a desired pattern. The seed layer may be formed by high speed printing, such as rotary screen printing, flat bed printing, rotary gravure printing, etc. The plated layer may comprise any conductive material which can by formed by plating, such as copper, nickel, cobalt or their alloys. The plated layer may be formed by electroplating by selectively forming the plated layer on the seed layer which is used as one of the electrodes in a plating bath. Alternatively, the plated layer may be formed by electroless plating. Alternatively, the conductor 15 may comprise a plurality of metal wires, such as copper, aluminum, and/or their alloy wires, which are supported by or attached to the carrier 13. The wires or the traces 15 electrically contact a major portion of a surface of the first polarity electrode 7 of the first photovoltaic cell 3a to collect current from this cell 3a. The wires or the traces 15 also electrically contact at least a portion of the second polarity electrode 9 of the second photovoltaic cell 3b to electrically connect this electrode 9 of cell 3b to the first polarity electrode 7 of the first photovoltaic cell 3a. The wires or traces 15 may form a grid-like contact to the electrode 7. The wires or traces 15 may include thin gridlines as well as optional thick busbars or buslines. If busbars or buslines are present, then the gridlines may be arranged as thin “fingers” which extend from the busbars or buslines.

The module that includes a collector-connector provides a current collection and interconnection configuration and method that is less expensive, more durable, and allows more light to strike the active area of the photovoltaic module than the prior art modules. The module provides collection of current from a photovoltaic cell and the electrical interconnection of two or more PV cells for the purpose of transferring the current generated in one PV cell to adjacent cells and/or out of the photovoltaic module to the output connectors. In addition, the carrier is may be easily cut, formed, and manipulated. In addition, when interconnecting thin-film solar cells with a metallic substrate, such as stainless steel, the embodiments of the invention allow for a better thermal expansion coefficient match between the interconnecting solders used and the solar cell than with traditional solder joints on silicon PV cells). In particular, the cells of the module may be interconnected without using soldered tab and string interconnection techniques of the prior art. However, soldering may be used if desired.

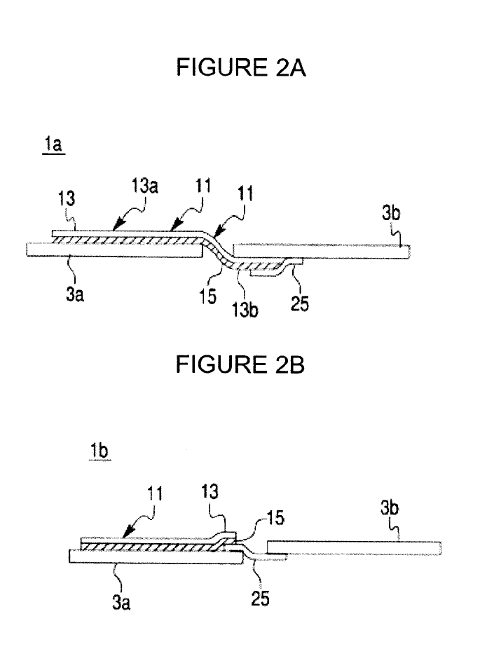

FIGS. 2A and 2B illustrate modules 1a and 1b, respectively, in which the carrier film 13 contains conductive traces 15 printed on one side. The traces 15 electrically contact the active surface of cell 3a (i.e., the front electrode 7 of cell 3a) collecting current generated on that cell 3a. A conductive interstitial material may be added between the conductive trace 15 and the cell 3a to improve the conduction and/or to stabilize the interface to environmental or thermal stresses. The interconnection to the second cell 3b is completed by a conductive tab 25 which contacts both the conductive trace 15 and the back side of cell 3b (i.e., the back side electrode 9 of cell 3b). The tab 25 may be continuous across the width of the cells or may comprise intermittent tabs connected to matching conductors on the cells. The electrical connection can be made with conductive interstitial material, conductive adhesive, solder, or by forcing the tab material 25 into direct intimate contact with the cell or conductive trace. Embossing the tab material 25 may improve the connection at this interface. In the configuration shown in FIG. 2A, the collector-connector 11 extends over the back side of the cell 3b and the tab 25 is located over the back side of cell 3b to make an electrical contact between the trace 15 and the back side electrode of cell 3b. In the configuration of FIG. 2B, the collector-connector 11 is located over the front side of the cell 3a and the tab 25 extends from the front side of cell 3a to the back side of cell 3b to electrically connect the trace 15 to the back side electrode of cell 3b.

In summary, in the module configuration of FIGS. 2A and 2B, the conductor 15 is located on one side of the carrier film 13. At least a first part 13a of carrier 13 is located over a front surface of the first photovoltaic cell 3a such that the conductor 15 electrically contacts the first polarity electrode 7 on the front side of the first photovoltaic cell 3a to collect current from cell 3a. An electrically conductive tab 25 electrically connects the conductor 15 to the second polarity electrode 9 of the second photovoltaic cell 3b. Furthermore, in the module 1a of FIG. 2A, a second part 13b of carrier 13 extends between the first photovoltaic cell 3a and the second photovoltaic cell 3b, such that an opposite side of the carrier 13 from the side containing the conductor 15 contacts a back side of the second photovoltaic cell 3b. Other interconnect configurations described in U.S. patent application Ser. No. 11/451,616 filed on Jun. 13, 2006 may also be used.

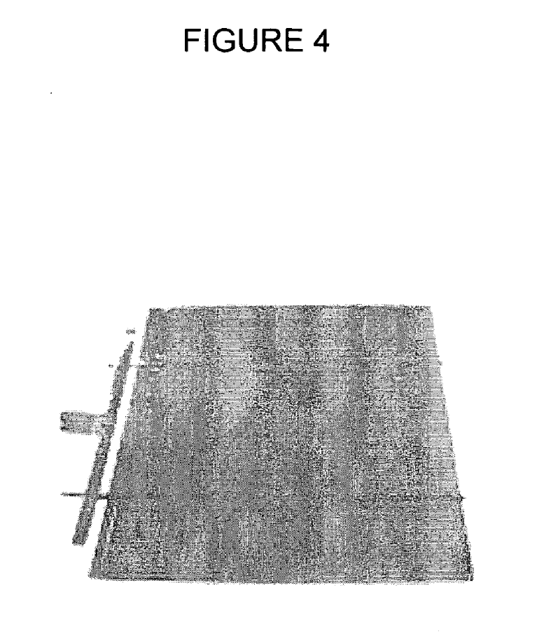

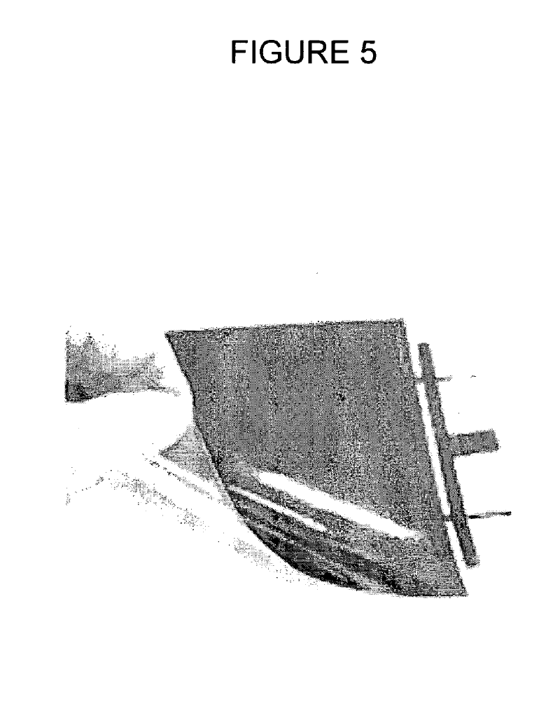

FIGS. 4 and 5 are photographs of flexible CIGS PV cell modules formed on flexible stainless steel substrates. The collector-connector containing a flexible insulating carrier and conductive traces shown in FIG. 2A and described above is formed over the top of the cells. The carrier comprises a PET/EVA co-extrusion and the conductor comprises electrolessly plated copper traces. FIG. 5 illustrates the flexible nature of the cell, which is being lifted and bent by hand.

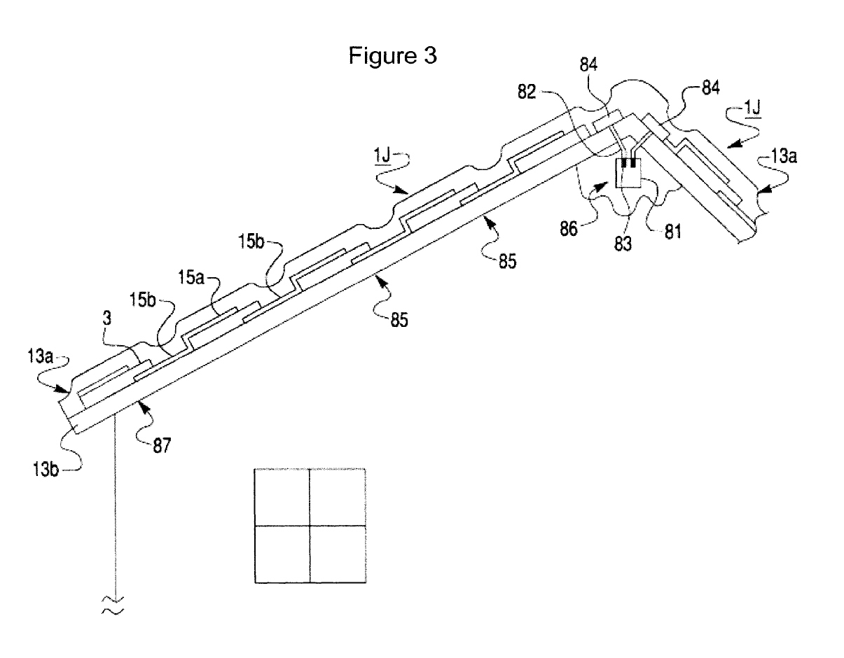

In some embodiments, the collector-connector can include two electrically insulating materials for building integrated photovoltaic (BIPV) applications. FIG. 3 illustrates a photovoltaic module with such collector-connector having a first carrier 13a and a second carrier 13b.

While the carriers 13 may comprise any suitable polymer materials, in one embodiment of the invention, the first carrier 13a comprises a thermal plastic olefin (TPO) sheet and the second carrier 13b comprises a second thermal plastic olefin membrane roofing material sheet which is adapted to be mounted over a roof support structure. Thus, in this aspect of the invention, the photovoltaic module 1j shown in FIG. 3 includes only three elements: the first thermal plastic olefin sheet 13a supporting the upper conductors 15a on its inner surface, a second thermal plastic olefin sheet 13b supporting the lower conductors 15b on its inner surface, and a plurality photovoltaic cells 3 located between the two thermal plastic olefin sheets 13a, 13b. The electrical conductors 15a, 15b electrically interconnect the plurality of photovoltaic cells 3 in the module, as shown in FIG. 3.

Preferably, this module 1j is a building integrated photovoltaic (BIPV) module which can be used instead of a roof in a building (as opposed to being installed on a roof) as shown in FIG. 3. In this embodiment, the outer surface of the second thermal plastic olefin sheet 13b is attached to a roof support structure of a building, such as plywood or insulated roofing deck. Thus, the module 1j comprises a building integrated module which forms at least a portion of a roof of the building.

If desired, an adhesive is provided on the back of the solar module 1j (i.e., on the outer surface of the bottom carrier sheet 13b) and the module is adhered directly to the roof support structure, such as plywood or insulated roofing deck. Alternatively, the module 1j can be adhered to the roof support structure with mechanical fasteners, such as clamps, bolts, staples, nails, etc. As shown in FIG. 3, most of the wiring can be integrated into the TPO back sheet 13b busbar print, resulting in a large area module with simplified wiring and installation. The module is simply installed in lieu of normal roofing, greatly reducing installation costs and installer markup on the labor and materials. For example, FIG. 3 illustrates two modules 1j installed on a roof or a roofing deck 85 of a residential building, such as a single family house or a townhouse. Each module 1j contains output leads 82 extending from a junction box 84 located on or adjacent to the back sheet 13b. The leads 82 can be simply plugged into existing building wiring 81, such as an inverter, using a simple plug-socket connection 83 or other simple electrical connection, as shown in a cut-away view in FIG. 3. For a house containing an attic 86 and eaves 87, the junction box 84 may be located in the portion of the module 1j (such as the upper portion shown in FIG. 3) which is located over the attic 86 to allow the electrical connection 83 to be made in an accessible attic, to allow an electrician or other service person or installer to install and/or service the junction box and the connection by coming up to the attic rather than by removing a portion of the module or the roof.

In summary, the module 1j may comprise a flexible module in which the first thermal plastic olefin sheet 13a comprises a flexible top sheet of the module having an inner surface and an outer surface. The second thermal plastic olefin sheet 13b comprises a back sheet of the module having an inner surface and an outer surface. The plurality of photovoltaic cells 3 comprise a plurality of flexible photovoltaic cells located between the inner surface of the first thermal plastic olefin sheet 13a and the inner surface of the second thermal plastic olefin sheet 13b. The cells 3 may comprise CIGS type cells formed on flexible substrates comprising a conductive foil. The electrical conductors include flexible wires or traces 15a located on and supported by the inner surface of the first thermal plastic olefin sheet 13a, and a flexible wires or traces 15b located on and supported by the inner surface of the second thermal plastic olefin sheet 13b. As in the previous embodiments, the conductors 15 are adapted to collect current from the plurality of photovoltaic cells 3 during operation of the module and to interconnect the cells. While TPO is described as one exemplary carrier 13 material, one or both carriers 13a, 13b may be made of other insulating polymer or non-polymer materials, such as EVA and/or PET for example, or other polymers which can form a membrane roofing material. For example, the top carrier 13a may comprise an acrylic material while the back carrier 13b may comprise PVC or asphalt material.

The carriers 13 may be formed by extruding the resins to form single ply (or multi-ply if desired) membrane roofing and then rolled up into a roll. The grid lines and busbars 15 are then printed on large rolls of clear TPO or other material which would form the top sheet of the solar module 1j. TPO could replace the need for EVA while doubling as a replacement for glass. A second sheet 13b of regular membrane roofing would be used as the back sheet, and can be a black or a white sheet for example. The second sheet 13b may be made of TPO or other roofing materials. As shown in FIG. 3, the cells 3 are laminated between the two layers 13a, 13b of pre-printed polymer material, such as TPO.

The top TPO sheet 13a can replace both glass and EVA top laminate of the prior art rigid modules, or it can replace the Tefzel/EVA encapsulation of the prior art flexible modules. Likewise, the bottom TPO sheet 13b can replace the prior art EVA/Tedlar bottom laminate. The module 1j architecture would consist of TPO sheet 13a, conductor 15a, cells 3, conductor 15b and TPO sheet 13b, greatly reducing material costs and module assembly complexity. The modules 1j can be made quite large in size and their installation is simplified. If desired, one or more luminescent dyes which convert shorter wavelength (i.e., blue or violet) portions of sunlight to longer wavelength (i.e., orange or red) light may be incorporated into the top TPO sheet 13a.

An additional device, such as a sensor, a data storage device, an antenna or a status indicator, can be integrated into the photovoltaic module by a variety of ways. In one example, the additional device(s) can be integrated into the module by being located physically between carriers 13, such as the first carrier 13a and the second carrier 13b in FIG. 3. In another example, the additional device(s) are electrically integrated with the module. In some embodiments, the integration involves adding one or more additional conductors 15 into the collector-connector of the module. In some embodiments, one or more photovoltaic cells of the module can be configured to be used as an additional device.

### Sensor

In some embodiments, the photovoltaic module comprises at least one sensor integrated in the module. Such a sensor can be configured in the photovoltaic module to detect at least one parameter, such as a change in the parameter which affects at least one photovoltaic cell of the module. In some embodiments, a sensor can be also configured to modify a performance of the module in response to a detected change.

### Strain Gauge

In some embodiments, the sensor can be a strain gauge. For example, the strain gauge can detect a strain in the module caused, for example, by unsafe loading conditions or by accumulations on the module, such as snow, leaves, debris or branches. The detected strain can lead to shutting down of the module automatically or by the operator. The detected strain can also be recorded in a data storage device and be used as an evidence in warranty claims.

The strain gauge can also be used for detecting a strain caused by a snow accumulated on the photovoltaic module during known snow fall periods. In such a case, a response to the detected strain can be reversing a bias applied to the module to heat the module to melt the snow. A special algorithm can be developed distinguish snow from other accumulations such as leaves, debris or branches based on a number of strain gauges in the module detecting a change in strain.

The strain gauge can also be used for monitoring cyclic loading, which might result in fatigue failure of the module. The strain gauge can also indicate whether the module is mounted correctly. In addition, the strain gauge can be used to monitor adhesion of the laminate layers in the module by detecting a change in strain resulting from delamination.

### Local Temperature Sensor

In some embodiments, the sensor can be a local temperature sensor, i.e. a sensor for detecting a temperature in one or more localized spots in the module. Detecting a high temperature in such localized spots can lead to reconfiguring of the module in a more efficient interconnection configuration or by lowering the overall power output of the module. The reconfiguration of the module can be performed as detailed in a co-pending application Ser. No. 11/639,428 filed on Dec. 15, 2006 titled “PHOTOVOLTAIC MODULE UTILIZING A FLEX CIRCUIT FOR RECONFIGURATION”, incorporated herein by reference in its entirety.

The local temperature sensor can be also used for controlling a cooling system of the module. The cooling system of the module can comprise, for example, a spray of cool water, a separate water pipe or a Peltier coil, which, in some embodiments, can be integrated in the module.

In some embodiments, the local temperature sensor can be a part of a flexible circuit of the module. In such a case, the flexible circuit comprises one or more thermocouples formed by junction layers of appropriate metals located together with the conductors 15.

### Irradiance Sensor

In some embodiments, a sensor can be an irradiance sensor, i.e. a device for detecting a flux of radiation on a surface of the module. The irradiance sensor can be a photodetector such as a photointensity detector. The irradiance sensor can also be an analog pyrometer. In response to a signal from the irradiance sensor, a configuration can be adjusted so that the flux of the radiation and thus the power output of the module are maximized. The adjustment of the module's configuration can be performed as detailed in the co-pending application “PHOTOVOLTAIC MODULE UTILIZING A FLEX CIRCUIT FOR RECONFIGURATION” to R. Dorn et al.

The irradiance sensor can be also used for determining an excessive build up of dirt of the module. In response, the module can be cleaned by, for example, spraying the module with water or other appropriate solvent or by vibrating the module with a piezo element, which can be also integrated in the module.

In some embodiments, the irradiance sensor can comprise one or more photovoltaic cells of the module configured to detect a flux of radiation on their surface.

In some embodiments, the irradiance sensor can be used in a tracking configuration of the module used to maintain maximum power output of the module.

### Output Voltage, Current and/or Power Sensor

In some embodiments, a sensor can be a sensor configured to detect an output voltage, current and/or power of the module, such as a voltmeter or an ammeter. Such a sensor can be used for maximizing power output of the module. Maximizing the power output of the module can be performed, for example, by reconfiguring module as detailed in the co-pending application “PHOTOVOLTAIC MODULE UTILIZING A FLEX CIRCUIT FOR RECONFIGURATION” to R. Dorn et al. Also, such a sensor can be used for tracking total energy produced by the module. Such information may be needed, for example, for certain renewable energy rebate programs or for customers who want to sell renewable energy certificates (REC) or CO₂ certificates.

The output current can be determined using a shunt resistor in series with one or more photovoltaic cells of the module. The determined output current can indicate whether the one or more photovoltaic cells are connected to the array or not. Such determination can be performed, for example, in a case of shading or hotspots in the module or a damage to the module.

### Other Sensors

In some embodiments, the sensor can be a fire detector, such as a smoke detector or a flame detector. The fire detector may interface with a security monitoring system. In response to a signal from the fire detector, the module can be put in a safe state during a fire, such as being shut down automatically. The fire detector can be also used for transmitting an alarm to inside the building and/or outside building, e.g. to a firehouse or an alarm company.

In some embodiments, a sensor can be configured to detect one or more weather conditions, such as wind direction, wind speed, atmospheric pressure, ambient temperature or humidity. Such a sensor can be used to control the module and/or building systems, such as heating and cooling systems of the building, in response to changing weather conditions.

In some embodiments, a sensor can be an accelerometer. The accelerometer can be used to detect trauma to the module in shipping, during installation or after installation from wind, hail, wildlife or other projectiles. The accelerometer can be also used for detecting whether the module is properly oriented.

In some embodiments, a sensor can be a humidity sensor integrated into the internal structure of laminates. Such a sensor can be used for detecting humidity or moisture impregnation into the sensor. The humidity sensor can also be used for detecting time to failure for the module due to the humidity or moisture impregnation.

In some embodiments, a sensor can be configured to measure byproducts of corrosion. Such a sensor can be used as a predictor of the module's failure.

In some embodiments, a sensor can be a motion sensor or a camera, which can be a part of a surveillance or a security system.

In some embodiments, a sensor can be configured to measure a reverse current. Such a sensor can be used for tracking potentially damaging events experienced by the module.

In some embodiments, a sensor can be a location sensor, such as a GPS receiver. Such a sensor can be used for determining an optimal orientation for the module for a particular location and/or altitude.

In some embodiments, a sensor can be configured to measure a market price of the energy or building energy demands. Such a sensor can be, for example, a computer connected to internet. The output of such a sensor can be used for optimizing storage, sale and use of energy by the module.

### Status Indicators

In some embodiments, the photovoltaic module can include one or more status indicators, such as light emitting diodes (LEDs) embedded in the module. Status indicators display a status of the module, e.g. whether the module is properly connected, whether the polarity of connection is correct, whether the grounding of the module is done properly, or if the module is operating properly.

In some embodiments one or more status indicators can be placed on an individual photovoltaic cell of the module. Such indicators can display whether the cell is underperforming, whether the cell is bypassed or whether the cell has a hot spot.

In some embodiments, status indicators could be also used for designating wiring configuration of the photovoltaic cells in the module.

### Data Storage Device

In some embodiments, the module can include one or more data storage devices. Such devices are configured to store or record at least one parameter of at least one photovoltaic cell of the module. Stored data can be data from one or more sensors or one or more status indicators. For example, the stored data can include power output, current, voltage, temperature and irradiation of the module as well as the information on module's status. The stored data can be used for monitoring the module's performance or for diagnostic purposes. The stored data can be also used for optimizing module's performance as a part of optimization algorithm. The stored data can be also used for analyzing module's failure for warranty claims.

The stored data can be displayed on a display integrated in the module or can be transmitted externally. In some embodiments, for external data transmission, the module can be equipped with a wired connection, an optical connection or a wireless connection, such as a connection under WiFi or Ethernet standards, to transmit data to a computer and/or a control or monitoring center.

The data storage device can be a memory chip integrated into the module or a computer, which is connected to the module via a wired connection, an optical connection or a wireless connection.

### Antenna

In some embodiments, when the module comprises a flexible circuit, the flexible circuit can be configured so that it acts as an antenna for receiving and/or transmitting electromagnetic radiation. Such an antenna can be formed by one or more conductive traces in the flexible circuit of the module.

In some embodiments, the antenna can be used for receiving TV, radio, cell phone or satellite signals. In some embodiments, a device, such as a TV or radio set, receiving a signal via the antenna can be located inside a building, on which the module is located. In some embodiments, a device receiving a signal via the antenna can be electrically connected to the antenna.

In some embodiments, the antenna can be also used as an antenna for radio frequency identification (RFID) tags. Such tags can be integrated into the module and could be used for tracking materials in manufacturing process of the module, while servicing the module or at the end of the module's life.

### Display

In some embodiments, the module can comprise a display. Such display can be an array of LEDs, filament or fluorescent lights, an electrochromic display, an electroluminescent display, an organic light emitting device (OLED) display or a liquid crystal display (LCD). In some embodiments, the display can comprise one or more status indicators discussed above.

The display can be used for a variety of informational or decorative purposes. For example, the display can be used for architectural customization or other aesthetic enhancements; as a seasonal holiday lighting display; as a safety beacon for locating an address in emergency situations such as during fire, police or ambulance responder situations; for entertainment or for displaying visual information, such as advertisements.

### AC Disconnect

In some embodiments, the photovoltaic module can include a smart AC disconnect. Such a disconnect can be configured to disconnect the photovoltaic cells of the module in response to a change in one or more parameters affecting at least one photovoltaic cell of the module. The information on the parameter change can be supplied to the AC disconnect from one of the sensors discussed above or from a surge protector.

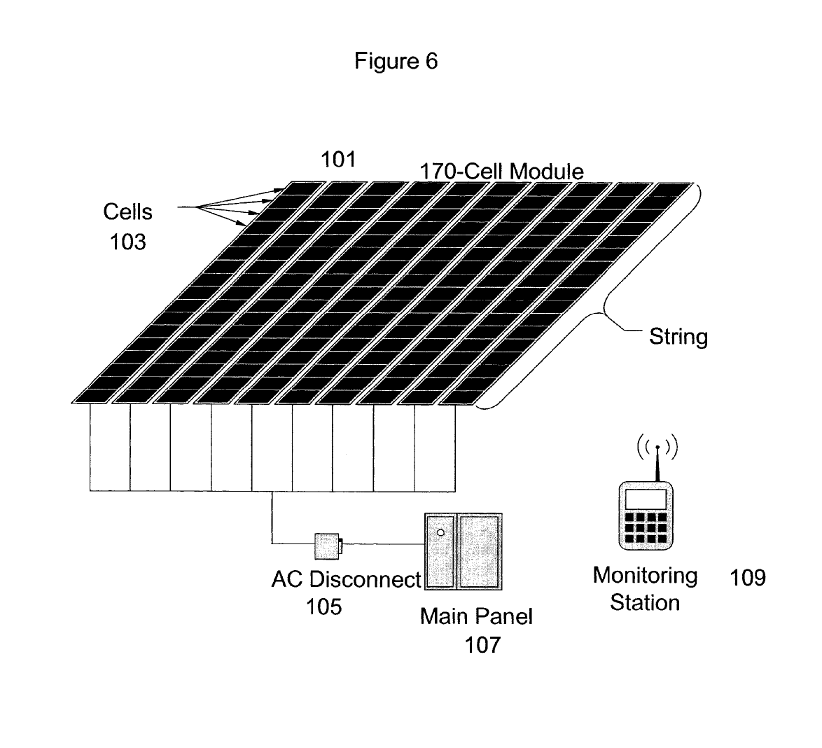

FIG. 6 schematically illustrates a 170 cell module 101 that includes a smart AC disconnect 105, photovoltaic cells 103, a main panel 107 and a monitoring station 109. The monitoring station 109 receives an information on parameters affecting the photovoltaic cells 103 from sensors (not shown in FIG. 6) integrated in the module 101 or from a surge protector. The monitoring station 109 is connected with the sensors via a wired, wireless or optical connection. The monitoring station is also connected with the smart disconnect via a wired, wireless or optical connection. In some embodiments, the smart AC disconnect can be integrated into the monitoring station. If an information on a change in one of the parameters that requires shutting off the module reaches the monitoring station 109, the monitoring station sends a signal to the smart AC disconnect 105 to electrically disconnect the module 101 from the main panel 107.

### Supplemental Devices

The photovoltaic device can also include one or more supplemental devices. Such devices can be used for enhancing efficiency of the module. For example, such supplemental devices can be used for active cooling of the module in case of overheating. Such active cooling device can be a water spray, a water pipe in a thermal contact with the module or a Peltier coil in a thermal contact with the module. In some embodiments, the Peltier coil can be integrated into the module.

The supplemental devices can be also used for passive cooling of the module. For example, a metal conductor in a flexible circuit of the module can be used for conductive or radiant heat transfer from the module. Passive cooling can also be performed using an optical device that selectively reflects light radiation with wavelengths outside of the active spectrum of the module, i.e. with wavelengths that do not produce a photovoltaic effect in the module and thus can cause an excessive heating of the module if absorbed. Such an optical device can be an optical filter or an optical coating disposed on the photovoltaic cells of the module.

The module can also include one or more devices capable of utilizing the energy that would be otherwise wasted by the module. If there is a temperature difference in the module, such device can be a Peltier coil, which can be used to produce electricity from the temperature difference. If the module produces vibrations, the energy of the vibrations can be harvested using a vibration transducer device, such as a piezo element, which converts the energy of vibrations into electrical energy. The collected energy that would be otherwise wasted can be used for various valuable purposes such as heating, cooling or additional electrical power.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

1. A photovoltaic module, comprising:
(A) a plurality of photovoltaic cells comprising (i) a first photovoltaic cell, (ii) a second photovoltaic cell, and (iii) a flexible collector-connector that is configured to collect current from the first photovoltaic cell and to electrically connect the first photovoltaic cell to the second photovoltaic cell;
wherein:
the collector-connector comprises a first and second electrically insulating carrier supporting at least one electrically conductive wire;
the first electrically insulating carrier is located over a front surface of the first photovoltaic cell such that a first part of the at least one electrically conductive wire electrically contacts a first polarity electrode on a front side of the first photovoltaic cell to collect current from the first photovoltaic cell; and
the second electrically insulating carrier extends over a back side of the second photovoltaic cell, such that a second part of the at least one electrically conductive wire contacts a second polarity electrode on a back side of the second photovoltaic cell to electrically connect the first photovoltaic cell to the second photovoltaic cell,
and
(B) at least one device integrated into the module and located between the first and second electrically insulating carriers, wherein the device comprises:
(a) a sensor configured to detect a change in one or more parameters affecting at least one of the plurality of photovoltaic cells;
(b) a data storage device configured to record at least one parameter of at least one of the plurality of photovoltaic cells; or
(c) an indicator configured to display a status of at least one cell of the plurality of photovoltaic cells.

2. The module of claim 1, comprising the sensor configured to detect a change in one or more parameters affecting at least one cell of the plurality of photovoltaic cells.

3. The module of claim 2, wherein the sensor is selected from the group consisting of a strain gauge, a temperature sensor, an irradiance sensor, a fire detector, an accelerometer, a humidity sensor, a corrosion byproduct sensor, a motion sensor or a surveillance camera, a GPS receiver/location sensor, a sensor configured to measure an output current or an output voltage of at least one cell of the plurality of photovoltaic cells.

4. The module of claim 1, further comprising a flexible circuit configured as an antenna for receiving and/or transmitting an electromagnetic radiation signal.

5. The module of claim 1, comprising the data storage device configured to record at least one parameter of at least one cell of the plurality of photovoltaic cells.

6. The module of claim 5, wherein the at least one parameter is selected from the group consisting of a power output, current, voltage, temperature, irradiation, system status, error message and a combination thereof.

7. The module of claim 5, wherein the data storage device is a memory chip configured to transmit data on the at least one parameter externally.

8. The module of claim 5, further comprising a display, which is electrically connected to the data storage device and which is configured to display data on the at least one parameter.

9. The module of claim 1, comprising one or more indicators configured to display a status of at least one cell of the plurality of the photovoltaic cells.

10. The module of claim 9, wherein the one or more indicators comprise a light emitting diode.

11. The module of claim 9, wherein at least one of the one or more indicators is placed on each of the plurality of the photovoltaic cells.

12. The module of claim 1, further comprising a decorative or informational display integrated in the module.

13. The module of claim 1, further comprising a smart AC disconnect configured to disconnect the plurality of photovoltaic cells in response to a change in one or more parameters affecting at least one of the plurality of photovoltaic cells.

14. The module of claim 1, further comprising a cooling device or a vibrational transducer device.

15. The module of claim 1, comprising at least two of:
(a) the sensor configured to detect a change in one or more parameters affecting at least one of the plurality of photovoltaic cells;
(b) the data storage device configured to record at least one parameter of at least one of the plurality of photovoltaic cells; or
(c) the indicator configured to display a status of at least one cell of the plurality of photovoltaic cells.

16. The module of claim 1, comprising:
(a) the sensor configured to detect a change in one or more parameters affecting at least one of the plurality of photovoltaic cells;
(b) the data storage device configured to record at least one parameter of at least one of the plurality of photovoltaic cells; and
(c) the indicator configured to display a status of at least one cell of the plurality of photovoltaic cells.

17. A photovoltaic module comprising
(A) a plurality of photovoltaic cells comprising (i) a first photovoltaic cell, (ii) a second photovoltaic cell, and (iii) a flexible collector-connector that is configured to collect current from the first photovoltaic cell and to electrically connect the first photovoltaic cell to the second photovoltaic cell,
wherein:
the collector-connector comprises a first and second electrically insulating carrier supporting at least one electrically conductive wire;
the first electrically insulating carrier is located over a front surface of the first photovoltaic cell such that a first part of the at least one electrically conductive wire electrically contacts a first polarity electrode on a front side of the first photovoltaic cell to collect current from the first photovoltaic cell; and
the second electrically insulating carrier extends over a back side of the second photovoltaic cell, such that a second part of the at least one electrically conductive wire contacts a second polarity electrode on a back side of the second photovoltaic cell to electrically connect the first photovoltaic cell to the second photovoltaic cell,
and
(B) a flexible circuit that is integrated in the module and located between the first and second electrically insulating carriers and is configured as an antenna for at least one of receiving or transmitting an electromagnetic radiation signal.

18. The module of claim 17, wherein the electromagnetic radiation signal is selected from the group consisting from a TV signal, a radio signal, a cellular phone signal, a satellite signal, a signal from one or more RFID tags and a combination thereof.

19. The module of claim 17, further comprising at least one device integrated into the module, the device comprising:
(a) a sensor configured to detect a change in one or more parameters affecting at least one cell of the plurality of photovoltaic cells;
(b) a data storage device configured to record at least one parameter of at least one cell of the plurality of photovoltaic cells; or
(c) an indicator configured to display a status of at least one cell of the plurality of photovoltaic cells.

20. A photovoltaic module, comprising:
(A) a plurality of photovoltaic cells comprising (i) a first photovoltaic cell, (ii) a second photovoltaic cell, and (iii) a flexible collector-connector that is configured to collect current from the first photovoltaic cell and to electrically connect the first photovoltaic cell to the second photovoltaic cell;
wherein:
the collector-connector comprises a first and second electrically insulating carrier supporting at least one electrically conductive wire;
the first electrically insulating carrier is located over a front surface of the first photovoltaic cell such that a first part of the at least one electrically conductive wire electrically contacts a first polarity electrode on a front side of the first photovoltaic cell to collect current from the first photovoltaic cell; and
the second electrically insulating carrier extends over a back side of the second photovoltaic cell, such that a second part of the at least one electrically conductive wire contacts a second polarity electrode on a back side of the second photovoltaic cell to electrically connect the first photovoltaic cell to the second photovoltaic cell,
(B) a sensor configured to detect at least one parameter affecting at least one cell of the plurality of photovoltaic cells, the sensor located between the first and second electrically insulating carriers, and
(C) a monitoring device connected to the sensor and configured to modify a performance of the photovoltaic module based on the at least one parameter detected by the sensor.

21. The module of claim 20, wherein the monitoring device is configured to shut off the module based on the at least one parameter detected by the sensor.

22. The module of claim 21, wherein the monitoring device is configured to shut off the module by electrically disconnecting the module from a panel or junction box based on the at least one parameter detected by the sensor.

23. The module of claim 20, wherein the monitoring device is configured to improve module performance based on the at least one parameter detected by the sensor.

24. The module of claim 23, wherein the at least one parameter comprises a strain on the photovoltaic module and the monitoring device is configured to reverse a bias applied to the photovoltaic module.

25. The module of claim 23, wherein the at least one parameter comprises a temperature and the monitoring device is configured to modify a performance of a cooling system of the photovoltaic module.

26. The module of claim 23, wherein the sensor is an irradiance sensor and the monitoring device is configured to modify a configuration of the module to maximize a radiance flux detected by the irradiance sensor.

27. The module of claim 23, wherein the sensor is an irradiance sensor configured to detect excessive dirt on the module and the monitoring device is configured to clean the module by spraying the module with water or exposing the module to vibrations from a piezo element.

28. The module of 20, furthering comprising a data storage device configured to record one at least one parameter detected by the at least one sensor and connected to the monitoring device and the sensor.

29. The module of 28, wherein the monitoring device is configured to modify a performance of the photovoltaic module based on a comparison of at least one parameter detected by the sensor and the at least one parameter recorded in the data storage device.
